(19) United States
(12) Patent Application Publication
(10) Pub. No.: US 2025/0016956 A1
(43) Pub. Date: Jan. 9, 2025

(54) REFRIGERANT CIRCULATION DEVICE

(71) Applicant: NIDEC CORPORATION, Kyoto (JP)

(72) Inventors: Toshihiko TOKESHI, Kyoto (JP); Takehito TAMAOKA, Kyoto (JP); Shinsuke HAMANO, Kyoto (JP); Taku MURAKAMI, Kyoto (JP); Tomoaki ANDO, Kyoto (JP); Hirotaka WATANABE, Kyoto (JP); Naoya NONOMURA, Kyoto (JP)

(21) Appl. No.: 18/763,393

(22) Filed: Jul. 3, 2024

Related U.S. Application Data
(60) Provisional application No. 63/525,018, filed on Jul. 5, 2023.

(51) Int. Cl. H05K 7/20

(52) U.S. Cl. CPC H05K 7/20272; H05K 7/20263; H05K 7/20763

(57) ABSTRACT

A refrigerant circulation device includes a primary flow path serving as a flow path of a primary refrigerant, a secondary flow path serving as a flow path of a secondary refrigerant, a heat exchanger connected to the primary flow path and the secondary flow path, a pump connected to the secondary flow path, and a housing including an accommodation region extending in a first direction and a second direction intersecting each other and having a dimension longer in the first direction than in the second direction. The housing accommodates the primary flow path, the secondary flow path, the heat exchanger, and the pump in the accommodation region. An entirety of the heat exchanger is positioned on one side in the second direction relative to the pump.

### CROSS-REFERENCE TO RELATED APPLICATIONS

The present application is a non-provisional application of U.S. Provisional Patent Application No. 63/525,018, filed on Jul. 5, 2023, the entire contents of which are hereby incorporated herein by reference.

### 1. FIELD OF THE INVENTION

The present disclosure relates to refrigerant circulation devices.

### 2. BACKGROUND

The refrigerant circulation device includes a heat exchanger. The heat exchanger is accommodated in a housing.

The cooling performance of the refrigerant circulation device can be improved by increasing the size of the heat exchanger. However, the housing of the refrigerant circulation device accommodates various members such as a pump that circulates the refrigerant in addition to the heat exchanger. For this reason, it may be difficult to increase the size of the heat exchanger.

### SUMMARY

An example embodiment of a refrigerant circulation device of the present disclosure includes a primary flow path serving as a flow path of a primary refrigerant, a secondary flow path serving as a flow path of a secondary refrigerant, a heat exchanger connected to the primary flow path and the secondary flow path, a pump connected to the secondary flow path, and a housing including an accommodation region. The accommodation region extends in a first direction and a second direction intersecting each other, and has a dimension longer in the first direction than in the second direction. The housing accommodates the primary flow path, the secondary flow path, the heat exchanger, and the pump in the accommodation region. An entirety of the heat exchanger is positioned on one side in the second direction relative to the pump.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a schematic view of a cooling system including a refrigerant circulation device according to an example embodiment of the present disclosure.

FIG. 2 is a perspective view of a refrigerant circulation device according to an example embodiment as viewed from above.

FIG. 3 is a perspective view of a refrigerant circulation device according to an example embodiment as viewed from below.

FIG. 4 is a perspective view showing an inside of a refrigerant circulation device according to an example embodiment of the present disclosure.

FIG. 5 is a plan view showing a primary flow path of a refrigerant circulation device according to an example embodiment of the present disclosure.

FIG. 6 is a plan view showing a secondary flow path (inlet side) of a refrigerant circulation device according to an example embodiment of the present disclosure.

FIG. 7 is a plan view showing the secondary flow path (outlet side) of a refrigerant circulation device according to an example embodiment of the present disclosure.

FIG. 8 is a perspective view of a heat exchanger of a refrigerant circulation device according to an example embodiment of the present disclosure.

FIG. 9 is a perspective view of a pump of a refrigerant circulation device according to an example embodiment of the present disclosure.

FIG. 10 is a perspective view of a heat exchanger and a tank of a refrigerant circulation device according to an example embodiment of the present disclosure.

FIG. 11 is a view showing a positional relationship between a heat exchanger and a pump of a refrigerant circulation device according to an example embodiment of the present disclosure.

FIG. 12 is a plan view of the refrigerant circulation device according to a refrigerant circulation device according to an example embodiment of the present disclosure.

FIG. 13 is a perspective view of a primary flow path and a secondary flow path of a CDU according to an example embodiment as viewed from an opposite side to the heat exchanger side.

### DETAILED DESCRIPTION

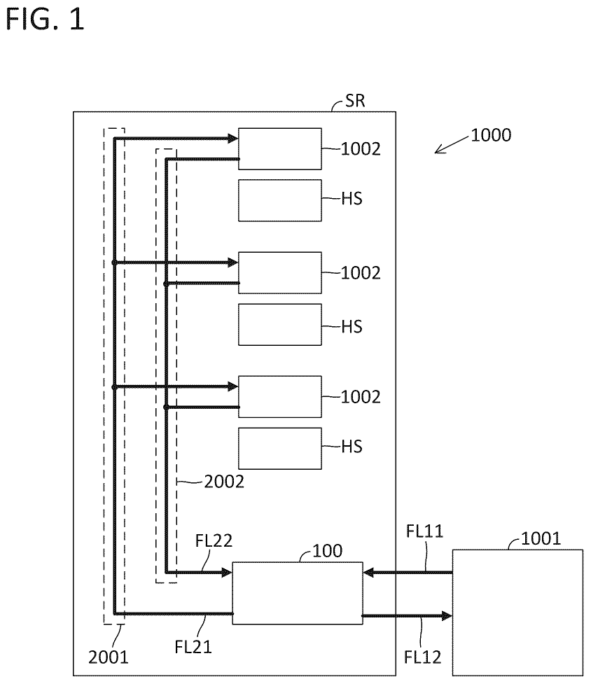

Example embodiments of the present disclosure will be described below with reference to FIGS. 1 to 12.

In the present description, for easy understanding, a configuration and an arrangement position of each member will be described using an XYZ orthogonal coordinate system. In the following description, a direction along the X axis is called an X direction, a side on which an arrow of the X axis faces is called one side in the X direction, and the opposite side is called the other side in the X direction. A direction along the Y axis is called a Y direction, a side on which an arrow of the Y axis faces is called one side in the Y direction, and the opposite side is called the other side in the Y direction. A direction along the Z axis is called a Z direction, a side on which an arrow of the Z axis faces is called one side in the Z direction, and the opposite side is called the other side in the Z direction.

The X direction corresponds to the “first direction”, the Y direction corresponds to the “second direction”, and the Z direction corresponds to a “third direction”. For example, the X direction and the Y direction are horizontal directions. The X direction is a front-rear direction, and the Y direction is a left-right direction. The Z direction is an up-down direction, one side in the Z direction is an upper side, and the other side in the Z direction is a lower side.

In the following description, it is assumed that each direction of the X direction, the Y direction, and the Z direction includes an error range (e.g., a range of about ±45°) allowable in the technical field to which the present disclosure belongs. As an example, “connected in the X direction” includes not only being connected in the X direction in a strict sense, but also being connected from a direction within a range of about ±45° with respect to the X direction. As another example, “extending in the X direction” includes not only extending in the X direction in a strict sense, but also extending in a direction shifted in a range of about ±45° with respect to the X direction.

In the following description, the term “intersect” includes lines, faces, and a line and a face intersecting each other at a right angle. The term “intersect” also includes lines, faces, and a line and a face intersecting each other at a non-right angle in a range of a minor difference. The minor difference includes a tolerance and an error.

FIG. 1 is a schematic view of a cooling system 1000 including a CDU 100 according to an example embodiment. Note that “CDU” is an abbreviation for “coolant distribution unit”.

The cooling system 1000 cools a heat source HS. For example, the heat source HS is a rack mounted server, a blade server, or the like, and is arranged inside a server rack SR. The heat source HS may be an electronic device different from the server, such as a projector, a personal computer, and a display. The heat source HS may be an electronic component such as a CPU, an electrolytic capacitor, a power semiconductor module, or a printed circuit board.

The cooling system 1000 includes the CDU 100. The CDU 100 corresponds to the “refrigerant circulation device”. The CDU 100 is arranged inside the server rack SR. However, the present disclosure is not limited to this. The CDU 100 may be arranged outside the server rack SR.

The CDU 100 sucks the primary refrigerant to the inside of the CDU 100 and pumps the primary refrigerant to the outside of the CDU 100. The CDU 100 sucks the secondary refrigerant to the inside of the CDU 100 and pumps the secondary refrigerant to the outside of the CDU 100. Since the inside of the CDU 100 is not provided with a pump on the primary refrigerant side, suction and pumping of the primary refrigerant in the CDU 100 are performed by an external pump. The CDU 100 performs heat exchange between the primary refrigerant and the secondary refrigerant. For example, refrigerant liquids such as antifreeze and pure water can be used as the primary refrigerant and the secondary refrigerant. Examples of the antifreeze usable as a refrigerant include an ethylene glycol aqueous solution and a propylene glycol aqueous solution. The types of the primary refrigerant and the secondary refrigerant may be the same as or may be different from each other. At least one of the primary refrigerant and the secondary refrigerant may be a gas refrigerant.

The CDU 100 is connected to flow paths FL11 and FL12. The CDU 100 sucks the primary refrigerant flowing through the flow path FL11 and pumps the primary refrigerant to the flow path FL12. The CDU 100 is connected to flow paths FL21 and FL22. The CDU 100 pumps the secondary refrigerant to the flow path FL21 and sucks the secondary refrigerant flowing through the flow path FL22.

A low-temperature primary refrigerant flows into the CDU 100. A high-temperature secondary refrigerant flows into the CDU 100. Inside the CDU 100, heat exchange is performed between the low-temperature primary refrigerant and the high-temperature secondary refrigerant. This cools the high-temperature secondary refrigerant.

The cooling system 1000 includes a cooling device 1001. The cooling device 1001 cools the primary refrigerant. The cooling device 1001 may be a device installed indoors or an outdoor facility such as a cooling tower. The cooling device 1001 is connected to the flow path FL11. The cooling device 1001 pumps the primary refrigerant to the CDU 100 via the flow path FL11. The cooling device 1001 is connected to the flow path FL12. The cooling device 1001 sucks the primary refrigerant from the CDU 100 via the flow path FL12.

The cooling system 1000 includes a cold plate 1002. The cold plate 1002 is connected to the flow paths FL21 and FL22. The cold plate 1002 has an internal flow path. The internal flow path of the cold plate 1002 extends from a connection point with the flow path FL21 and reaches a connection point with the flow path FL22. That is, the secondary refrigerant flows inside the cold plate 1002.

The cold plate 1002 is in thermal contact with the heat source HS. The cold plate 1002 may be in direct contact with the heat source HS or may be in indirect contact with the heat source HS via a heat transfer member such as a heat transfer sheet.

When the cold plate 1002 and the heat source HS are in thermal contact with each other, thermal energy of the heat source HS is transferred to the secondary refrigerant flowing inside the cold plate 1002. As a result, the heat source HS is cooled. The secondary refrigerant used for cooling of the heat source HS flows into the CDU 100 via the flow path FL22.

The number of heat sources HS installed for the server rack SR is not particularly limited. The number of heat sources HS installed for the server rack SR may be plural or one.

When the number of heat sources HS installed for the server rack SR is plural, the same number (i.e., a plurality) of cold plates 1002 as the number of heat sources HS installed are installed in the server rack SR. The cold plates 1002 come into thermal contact with the heat sources HS one by one.

When the number of the heat sources HS installed for the server rack SR is plural, for example, a part of the flow path FL21 is configured by a distribution manifold 2001, and a part of the flow path FL22 is configured by a collection manifold 2002.

The distribution manifold 2001 has one inflow port and a plurality of outflow ports. The secondary refrigerant flows into the inflow port of the distribution manifold from the CDU 100. The secondary refrigerant flowing from the inflow port of the distribution manifold flows out from each outflow port of the distribution manifold 2001. The outflow ports of the distribution manifold 2001 are connected to the cold plates 1002 different from one another. Due to this, the secondary refrigerant flows into the cold plates 1002.

The collection manifold 2002 has a plurality of inflow ports and one outflow port. The inflow ports of the collection manifold 2002 are connected to the cold plates 1002 different from one another. The secondary refrigerant flowing out of each cold plate 1002 flows into the collection manifold 2002 via each inflow port of the collection manifold 2002. The outflow port of the collection manifold 2002 is connected to the CDU 100. Due to this, the secondary refrigerant flowing out of each cold plate 1002 flows into the CDU 100.

FIG. 1 illustrates a case where the number of cold plates 1002 installed (i.e., the number of heat sources HS installed) is 3. In FIG. 1, a flowing direction of each refrigerant is indicated by an arrow orientation.

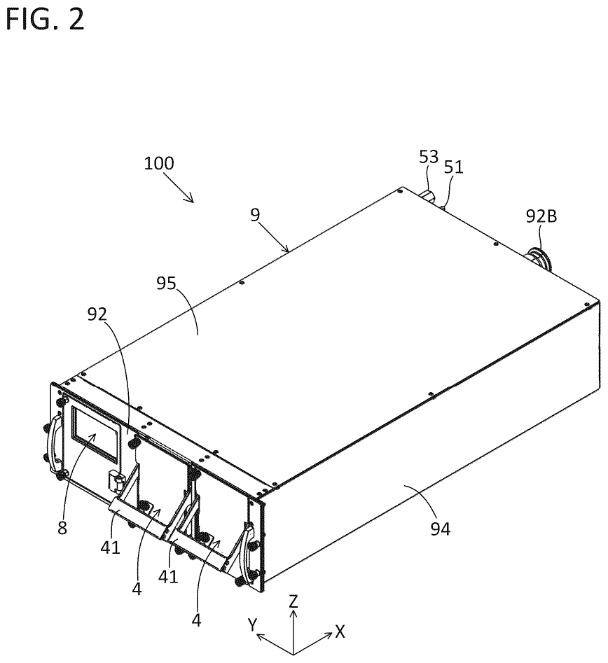

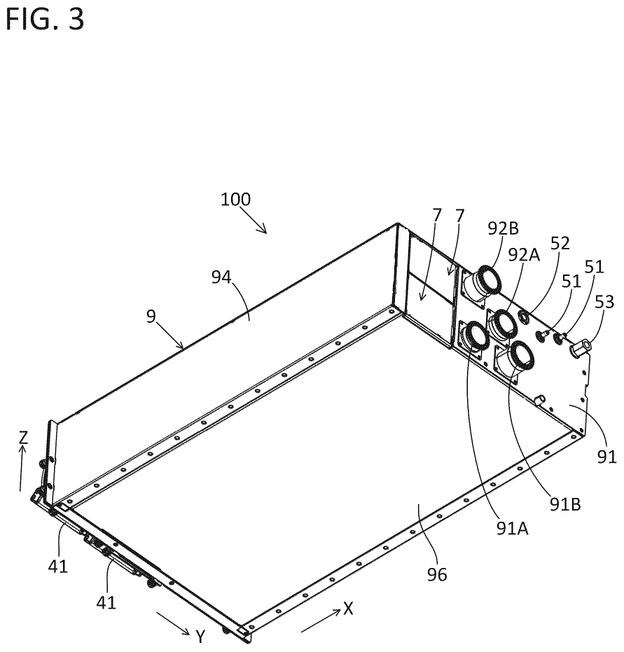

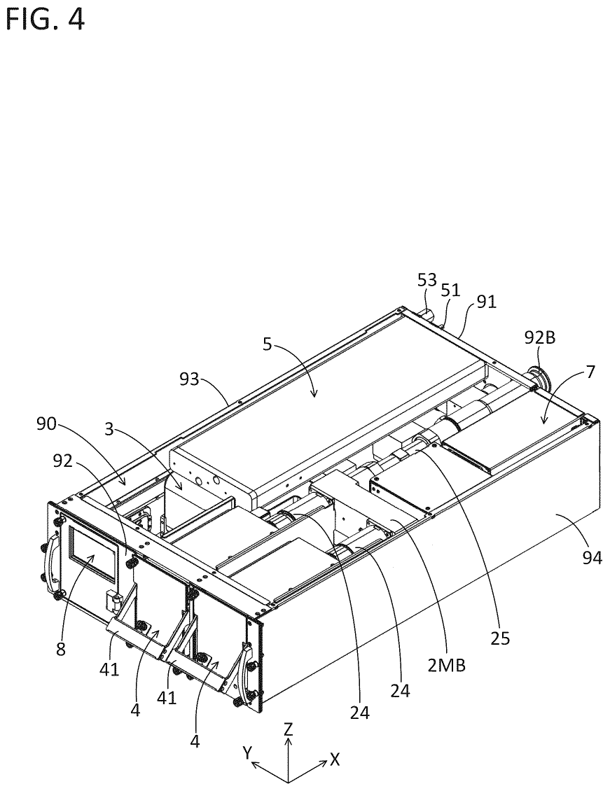

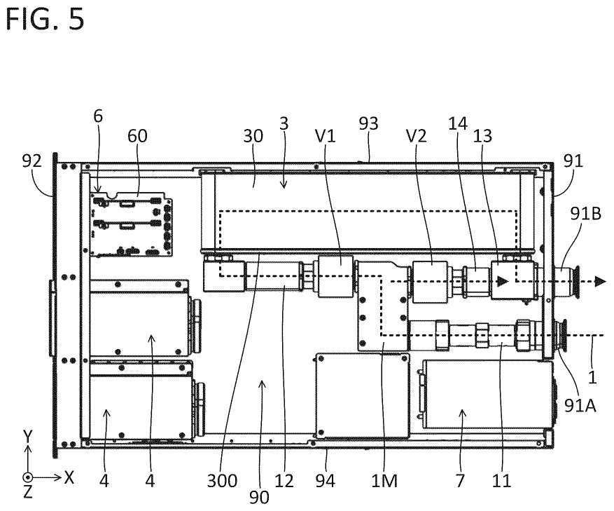

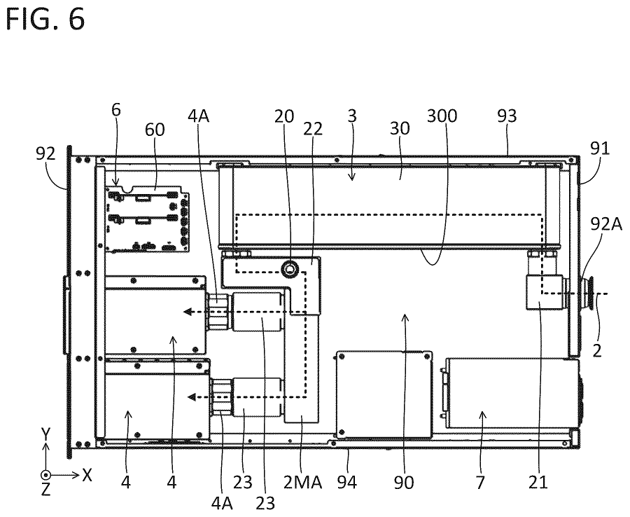

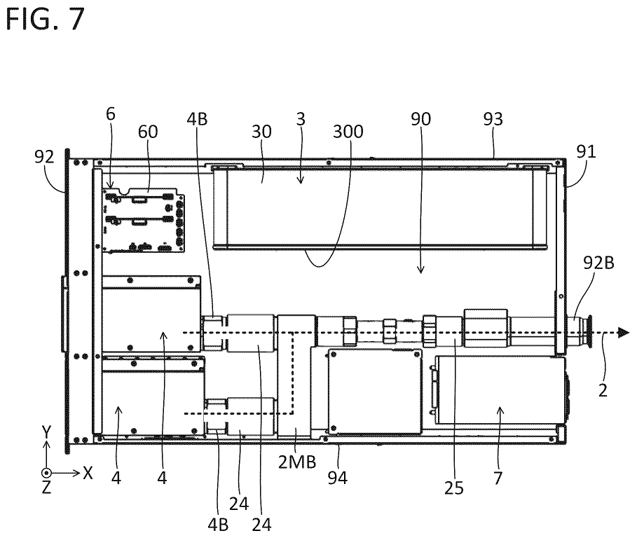

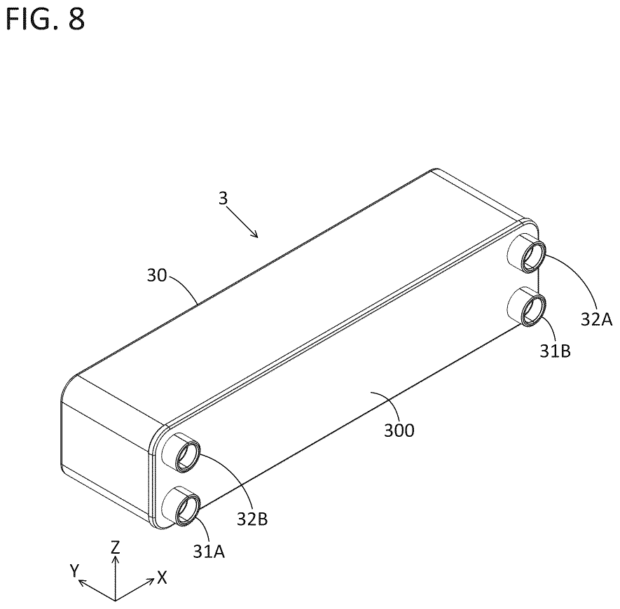

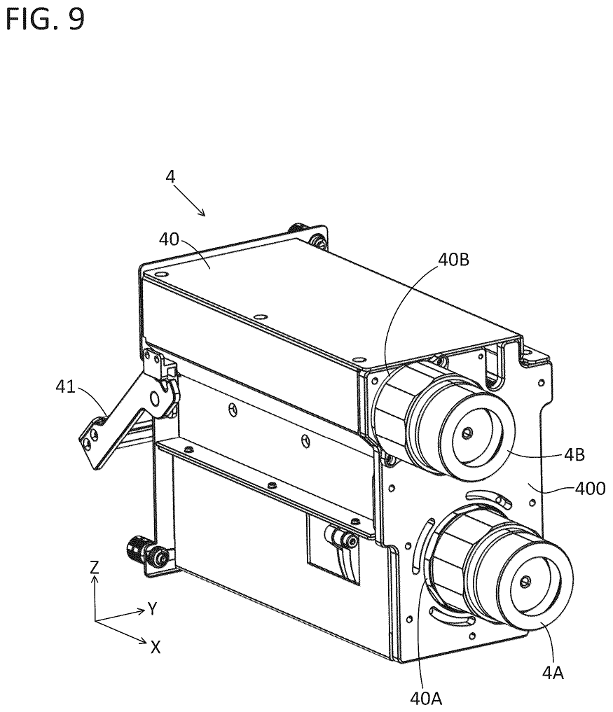

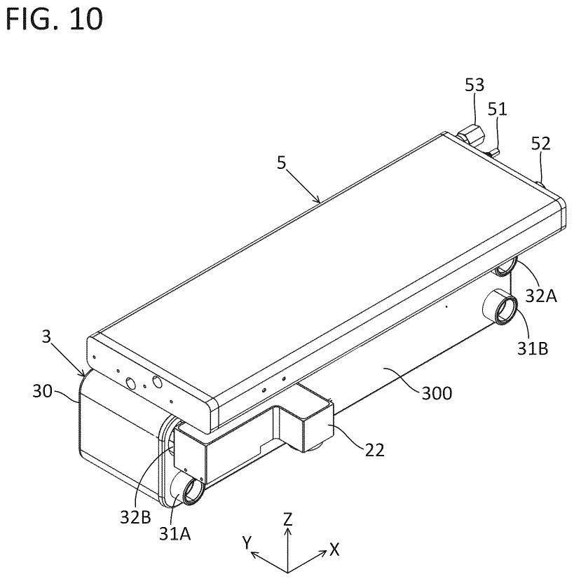

FIG. 2 is a perspective view of the CDU 100 according to the example embodiment as viewed from above. FIG. 3 is a perspective view of the CDU 100 according to the example embodiment as viewed from below. FIG. 4 is a perspective view showing the inside of the CDU 100 according to the example embodiment. FIG. 5 is a plan view showing a primary flow path 1 of the CDU 100 according to the example embodiment. FIG. 6 is a plan view showing a secondary flow path 2 (inlet side) of the CDU 100 according to the example embodiment. FIG. 7 is a plan view showing the secondary flow path 2 (outlet side) of the CDU 100 according to the example embodiment. FIG. 8 is a perspective view of a heat exchanger 3 of the CDU 100 according to the example embodiment. FIG. 9 is a perspective view of a pump 4 of the CDU 100 according to the example embodiment. FIG. 10 is a perspective view of the heat exchanger 3 and a tank 5 of the CDU 100 according to the example embodiment.

FIGS. 5 to 7 are plan views of the inside of the CDU 100 as viewed from one side in the Z direction (i.e., the upper side). In FIGS. 5 to 7, some of the components are omitted, and the refrigerant flow path is indicated by a broken line arrow. The direction in which the arrow is directed is the flowing direction of the refrigerant.

In FIG. 5, other refrigerant flow paths are omitted for clarifying the primary flow path 1. In FIG. 6, other refrigerant flow paths are omitted for clarifying the inlet side of the secondary flow path 2. In FIG. 7, other refrigerant flow paths are omitted for clarifying the outlet side of the secondary flow path 2.

The CDU 100 includes the primary flow path 1 and the secondary flow path 2. The primary flow path 1 serves as a flow path of the primary refrigerant. The secondary flow path 2 serves as a flow path of the secondary refrigerant.

The CDU 100 includes the heat exchanger 3. The heat exchanger 3 is connected to the primary flow path 1 and the secondary flow path 2. The primary refrigerant and the secondary refrigerant flow into the heat exchanger 3 and flow out of the heat exchanger 3. The heat exchanger 3 exchanges heat between the primary refrigerant and the secondary refrigerant inside the heat exchanger 3. The heat exchange system of the heat exchanger 3 is a plate system, for example.

The CDU 100 includes the pump 4. The pump 4 is connected to the secondary flow path 2. The pump 4 has an internal flow path. When the pump 4 is driven, the secondary refrigerant is sucked into the internal flow path of the pump 4, and the secondary refrigerant is pumped from the internal flow path of the pump 4. Due to this, the secondary refrigerant circulates between the CDU 100 and the cold plate 1002. The number of pumps 4 installed is not particularly limited. For example, the number of pumps 4 installed is 2. That is, the CDU 100 includes the plurality of pumps 4.

The CDU 100 includes the tank 5. The tank 5 stores a refrigerant used as the secondary refrigerant. The tank 5 is connected to the secondary flow path 2. The tank 5 can supply the refrigerant to the secondary flow path 2.

The CDU 100 includes a control circuit 6 and a power supply unit 7. The CDU 100 also includes a touchscreen 8.

The CDU 100 includes a housing 9. The housing 9 has an accommodation region 90. The housing 9 accommodates, in the accommodation region 90, the primary flow path 1, the secondary flow path 2, the heat exchanger 3, the pump 4, the tank 5, the control circuit 6, the power supply unit 7, and the touchscreen 8.

The accommodation region 90 has a substantially rectangular shape in which the X direction is a long direction and the Y direction is a short direction in plan view from the Z direction. That is, the accommodation region 90 extends in the X direction and the Y direction intersecting each other, and has a dimension longer in the X direction than in the Y direction. In the accommodation region 90, the Z direction is a depth direction. The width (depth) in the Z direction of the accommodation region 90 is smaller than each width in the X direction and the Y direction of the accommodation region 90.

The housing 9 has a plurality of panels 91 to 96. The plurality of panels 91 to 96 are made of sheet metal, for example. The plurality of panels 91 to 96 surround the accommodation region 90. That is, the housing 9 has a region surrounded by the plurality of panels 91 to 96 as the accommodation region 90.

The panels 91 and 92 are arranged to face each other in the X direction across the accommodation region 90. The panel 91 is arranged on one side in the X direction. The panel 92 is arranged on the other side in the X direction. That is, the panel 91 defines the accommodation region 90 by covering the accommodation region 90 from one side in the X direction. The panel 92 defines the accommodation region 90 by covering the accommodation region 90 from the other side in the X direction. The panels 91 and 92 define a width in the X direction of the accommodation region 90. In the following description, the panel 91 may be called a back panel 91, and the panel 92 may be called a front panel 92 to be distinguished from the other panels constituting the housing 9.

The panels 93 and 94 are arranged to face each other in the Y direction across the accommodation region 90. The panel 93 is arranged on one side in the Y direction. The panel 94 is arranged on the other side in the Y direction. That is, the panel 93 defines the accommodation region 90 by covering the accommodation region 90 from one side in the Y direction. The panel 94 defines the accommodation region 90 by covering the accommodation region 90 from the other side in the Y direction. The panels 93 and 94 define a width in the Y direction of the accommodation region 90.

The panels 95 and 96 are arranged to face each other in the Z direction across the accommodation region 90. The panel 95 is arranged on one side in the Z direction. The panel 96 is arranged on the other side in the Z direction. That is, the panel 95 defines the accommodation region 90 by covering the accommodation region 90 from one side in the Z direction. The panel 96 defines the accommodation region 90 by covering the accommodation region 90 from the other side in the Z direction. The panels 95 and 96 define a width in the Z direction of the accommodation region 90. The panel 95 serves as a lid covering the accommodation region 90 from above. The panel 96 serves as a bottom covering the accommodation region 90 from below.

The housing 9 has a housing primary inlet 91A. The housing primary inlet 91A is connected to the primary flow path 1 and serves as an inflow port of the primary refrigerant to the inside of the CDU 100. The housing 9 has a housing primary outlet 91B. The housing primary outlet 91B is connected to the primary flow path 1 and serves as an outflow port of the primary refrigerant from the inside of the CDU 100.

The housing 9 has a housing secondary inlet 92A. The housing secondary inlet 92A is connected to the secondary flow path 2 and serves as an inflow port of the secondary refrigerant to the inside of the CDU 100. The housing 9 has a housing secondary outlet 92B. The housing secondary outlet 92B is connected to the secondary flow path 2 and serves as an outflow port of the secondary refrigerant from the inside of the CDU 100.

The housing primary inlet 91A is connected to the flow path FL11 extending from the cooling device 1001. The housing primary outlet 91B is connected to the flow path FL12 extending from the cooling device 1001. Then, the primary refrigerant flows into the CDU 100 from the cooling device 1001 via the housing primary inlet 91A. The primary refrigerant flows out from the inside of the CDU 100 to the cooling device 1001 via the housing primary outlet 91B.

The housing secondary inlet 92A is connected to the flow path FL22 extending from the cold plate 1002. The housing secondary outlet 92B is connected to the flow path FL21 extending from the cold plate 1002. Due to this, the secondary refrigerant flows to the inside of the CDU 100 from the cold plate 1002 via the housing secondary inlet 92A. The secondary refrigerant flows from the inside of the CDU 100 to the cold plate 1002 via the housing secondary outlet 92B.

The housing primary inlet 91A, the housing primary outlet 91B, the housing secondary inlet 92A, and the housing secondary outlet 92B are arranged on the back panel 91. For example, the back panel 91 has four openings penetrating in the X direction. From each of the four openings, a tubular member in which the X direction is an axial direction protrudes to one side in the X direction relative to the back panel 91. The housing 9 has the four tubular members protruding from the back panel 91 to one side in the X direction as the housing primary inlet 91A, the housing primary outlet 91B, the housing secondary inlet 92A, and the housing secondary outlet 92B, respectively.

As shown in FIG. 5, the primary flow path 1 includes a manifold 1M and flow path pipes 11 to 13. The internal space of the manifold 1M serves as a flow path of the primary refrigerant, and each internal space of the flow path pipes 11 to 13 serves as a flow path of the primary refrigerant.

The manifold 1M has one inflow port (reference sign not shown) and two outflow ports (reference signs not shown). The primary refrigerant flowing in from the inflow port of the manifold 1M branches inside the manifold 1M and flows out from each of the two outflow ports of the manifold 1M.

The flow path pipe 11 is a straight pipe extending linearly in the X direction. The end on one side in the X direction of the flow path pipe 11 is connected to the housing primary inlet 91A. The end on the other side in the X direction of the flow path pipe 11 is connected to the inflow port of the manifold 1M. The flow path pipe 11 causes the primary refrigerant to flowing in from the housing primary inlet 91A (i.e., the cooling device 1001) flow into the inflow port of the manifold 1M.

The flow path pipe 12 has a straight pipe part and a bent part. The straight pipe part of the flow path pipe 12 extends linearly in the X direction. One side in the X direction of the straight pipe part of the flow path pipe 12 is connected to one of the outflow ports of the manifold 1M. The other side in the X direction of the straight pipe part of the flow path pipe 12 is connected to the bent part of the flow path pipe 12. The bent part of the flow path pipe 12 is an elbow that bends the flowing direction of the primary refrigerant by 90° from the X direction to the Y direction. The bent part of the flow path pipe 12 is connected in the Y direction with respect to the heat exchanger 3. The bent part of the flow path pipe 12 bends, by 90° in the Y direction, and flows, into the heat exchanger 3, the primary refrigerant flowing through the straight pipe part of the flow path pipe 12 in the X direction.

The flow path pipe 13 is an elbow that bends the flowing direction of the primary refrigerant by 90° from the Y direction to the X direction. The flow path pipe 13 is connected in the Y direction with respect to the heat exchanger 3 and is connected in the X direction with respect to the housing primary outlet 91B. The flow path pipe 13 bends, by 90° in the X direction, and flows out, to the housing primary outlet 91B, the primary refrigerant flowing in in the Y direction from the heat exchanger 3.

The primary flow path 1 further includes a bypass pipe 14. Of the two outflow ports of the manifold 1M, the outflow port different from the outflow port connected to the flow path pipe 12 is connected to the flow path pipe 13 via the bypass pipe 14. The bypass pipe 14 causes the primary refrigerant to flow from the manifold 1M to the flow path pipe 13.

The flow path pipe 12 is provided with a control valve V1 that controls the flow rate of the primary refrigerant in the flow path pipe 12. The bypass pipe 14 is provided with a control valve V2 that controls the flow rate of the primary refrigerant in the bypass pipe 14. With this configuration, the inflow amount of the primary refrigerant to the heat exchanger 3 can be adjusted by controlling the opening degrees of the control valves V1 and V2.

The secondary flow path 2 is classified into an inlet side (see FIG. 6) and an outlet side (see FIG. 7). On the inlet side of the secondary flow path 2, the secondary refrigerant is guided from the housing secondary inlet 92A to the heat exchanger 3, and the secondary refrigerant is guided from the heat exchanger 3 to the pump 4. On the outlet side of the secondary flow path 2, the secondary refrigerant is guided from the pump 4 to the housing secondary outlet 92B. Hereinafter, the secondary flow path 2 will be described separately on the inlet side and the outlet side.

As shown in FIG. 6, the inlet side of the secondary flow path 2 is configured by a manifold 2MA and flow path pipes 21 to 23. The internal space of the manifold 2MA serves as a flow path of the secondary refrigerant, and each internal space of the flow path pipes 21 to 23 serves as a flow path of the secondary refrigerant.

The manifold 2MA has one inflow port (reference sign not shown) and a plurality of outflow ports (reference signs not shown) The number of outflow ports of the manifold 2MA is the same as the number of pumps 4 installed. If the number of pumps 4 installed is 2, the number of outflow ports of the manifolds 2MA is 2. The secondary refrigerant flowing from one inflow port of the manifold 2MA branches inside the manifold 2MA and flows out from each of the plurality of outflow ports of the manifold 2MA.

The flow path pipe 21 is an elbow that bends the flowing direction of the secondary refrigerant by 90° from the X direction to the Y direction. The flow path pipe 21 is connected in the X direction with respect to the housing secondary inlet 92A and is connected in the Y direction with respect to the heat exchanger 3. The flow path pipe 21 bends, by 90° in the Y direction, the secondary refrigerant flowing in in the X direction from the housing secondary inlet 92A, and causes the secondary refrigerant to flow into the heat exchanger 3.

The flow path pipe 22 has an L shape. In other words, the flow path pipe 22 is a crank pipe. An end on an upstream side in the refrigerant flowing direction of the flow path pipe 22 is connected in the Y direction with respect to the heat exchanger 3. An end on a downstream side in the refrigerant flowing direction of the flow path pipe 22 is connected in the Z direction with respect to the inflow port of the manifold 2MA. The flow path pipe 22 causes the secondary refrigerant to flowing in from the heat exchanger 3 flow in the X direction, and then bends the secondary refrigerant by 90° in the Y direction and flows the secondary refrigerant into the inflow port of the manifold 2MA.

One flow path pipe 23 is allocated to each pump 4. Each flow path pipe 23 is a straight pipe extending in the X direction. The ends on one side in the X direction of the flow path pipes 23 are connected to the outflow ports different from one another of the manifold 2MA. The end on the other side in the X direction of each flow path pipe 23 is connected to the corresponding pump 4. Each flow path pipe 23 causes the secondary refrigerant to flow into the corresponding pump 4 from the manifold 2MA.

As shown in FIG. 7, the outlet side of the secondary flow path 2 is configured by a manifold 2MB and flow path pipes 24 and 25. The manifold 2MB has a plurality of inflow ports (reference signs not shown) and one outflow port (reference sign not shown). The number of inflow ports of the manifold 2MB is the same as the number of pumps 4 installed. If the number of pumps 4 installed is 2, the number of inflow ports of the manifolds 2MB is 2. The secondary refrigerants flowing in from the plurality of inflow ports of the manifold 2MB merge inside the manifold 2MB, and flow out from one outflow port of the manifold 2MB.

One flow path pipe 24 is allocated to each pump 4. Each flow path pipe 24 is a straight pipe extending linearly in the X direction. The ends on one side in the X direction of the flow path pipes 24 are connected to the inflow ports different from one another of the manifold 2MB. The end on the other side in the X direction of each flow path pipe 24 is connected to the corresponding pump 4. Each flow path pipe 24 causes the secondary refrigerant to flow into the manifold 2MB from the corresponding pump 4.

The flow path pipe 25 is a straight pipe extending linearly in the X direction. The end on one side in the X direction of the flow path pipe 25 is connected to the housing secondary outlet 92B. The end on the other side in the X direction of the flow path pipe 25 is connected to the outflow port of the manifold 2MB. The flow path pipe 25 causes the secondary refrigerant to flow from the outflow port of the manifold 2MB to the housing secondary outlet 92B. Due to this, the secondary refrigerant flows out from the housing secondary outlet 92B, and the secondary refrigerant flows into the cooling device 1001.

The heat exchanger 3 includes a plurality of heat transfer plates (not illustrated) stacked in the Y direction. In each heat transfer plate, the Y direction is a plate thickness direction. Each heat transfer plate has a substantially rectangular shape in which the X direction is a long direction and the Z direction is a short direction.

As shown in FIG. 8, the heat exchanger 3 includes a HEX housing 30. Note that “HEX” is an abbreviation for “heat exchanger”. The HEX housing 30 supports a stack body including a plurality of heat transfer plates. The HEX housing 30 may be a member including a pair of cover plates that sandwich, in the Y direction, the stack body including the plurality of heat transfer plates. The HEX housing 30 is a substantially cuboid having six outer faces. The HEX housing 30 has a pair of outer faces parallel to an XY plane, a pair of outer faces parallel to a YZ plane, and a pair of outer faces parallel to a ZX plane. In the HEX housing 30, the X direction is a long direction.

The heat exchanger 3 has a HEX primary inlet 31A, a HEX primary outlet 31B, a HEX secondary inlet 32A, and a HEX secondary outlet 32B. The HEX primary inlet 31A is connected to the primary flow path 1 and serves as an inflow port of the primary refrigerant to the inside of the heat exchanger 3. The HEX primary outlet 31B is connected to the primary flow path 1 and serves as an outflow port of the primary refrigerant from the inside of the heat exchanger 3. The HEX secondary inlet 32A is connected to the secondary flow path 2 and serves as an inflow port of the secondary refrigerant to the inside of the heat exchanger 3. The HEX secondary outlet 32B is connected to the secondary flow path 2 and serves as an outflow port of the secondary refrigerant from the inside of the heat exchanger 3.

The HEX primary inlet 31A, the HEX primary outlet 31B, the HEX secondary inlet 32A, and the HEX secondary outlet 32B are arranged on a flow path connection face 300. The flow path connection face 300 is one of the outer faces of the HEX housing 30. That is, the HEX housing 30 has the flow path connection face 300 on which the HEX primary inlet 31A, the HEX primary outlet 31B, the HEX secondary inlet 32A, and the HEX secondary outlet 32B are arranged.

The primary refrigerant flows to the inside of the heat exchanger 3 from the HEX primary inlet 31A, and flows out from the inside of the heat exchanger 3 via the HEX primary outlet 31B. The secondary refrigerant flows to the inside of the heat exchanger 3 from the HEX secondary inlet 32A, and flows out from the inside of the heat exchanger 3 via the HEX secondary outlet 32B.

Inside the heat exchanger 3, the surface of each heat transfer plate serves as a flow path of the refrigerant. Here, the heat transfer plates through which the primary refrigerant flows and the heat transfer plates through which the secondary refrigerant flows are alternately stacked. Due to this, heat of the high-temperature refrigerant (i.e., the secondary refrigerant) is transferred to the heat transfer plate, and the heat is transferred to the low-temperature refrigerant (i.e., the primary refrigerant).

The pump 4 has a pump rotor (not illustrated) on the internal flow path of the pump 4. The pump rotor rotates by power from a pump motor (not illustrated). When the pump rotor rotates, the secondary refrigerant is sucked and pumped. The type of the pump 4 is not particularly limited. As the pump 4, various pumps such as a centrifugal pump, a propeller pump, a rotary pump, a gear pump, and a screw pump can be used.

As shown in FIG. 9, the pump 4 includes a pump body 40. The pump body 40 includes the pump motor, the pump rotor, and pump cover covering them.

The pump 4 has a pump inlet 40A and a pump outlet 40B. The pump inlet 40A serves as an inflow port of the secondary refrigerant to the inside of the pump 4. The pump outlet 40B serves as an outflow port of the secondary refrigerant from the inside of the pump 4. The pump inlet 40A and the pump outlet 40B are arranged in the pump body 40.

For example, the pump cover includes a back cover 400 covering the pump motor, the pump rotor, and the like from one side in the X direction. The back cover 400 has a plate shape, and the X direction is a plate thickness direction. The back cover 400 has two openings penetrating in the X direction. From each of the two openings, a tubular member in which the X direction is an axial direction protrudes to one side in the X direction relative to the back cover 400. The pump 4 has two tubular members protruding from the back cover 400 to one side in the X direction as the pump inlet 40A and the pump outlet 40B, respectively. That is, the pump inlet 40A and the pump outlet 40B are open to one side in the X direction.

The pump 4 includes a pump inlet-side flow path 4A and a pump outlet-side flow path 4B. The pump inlet-side flow path 4A connects the pump inlet 40A and the secondary flow path 2. The pump inlet-side flow path 4A is connected to the flow path pipe 23 constituting a part of the secondary flow path 2. The pump outlet-side flow path 4B connects the pump outlet 40B and the secondary flow path 2. The pump outlet-side flow path 4B is connected to the flow path pipe 24 constituting a part of the secondary flow path 2.

For example, the flow path pipes 23 and 24 connected to the pump inlet-side flow path 4A and the pump outlet-side flow path 4B, respectively, are coupling sockets. Each of the pump inlet-side flow path 4A and the pump outlet-side flow path 4B is attachable to and detachable from the corresponding socket (i.e., the flow path pipes 23 and 24).

This makes the pump 4 attachable to and detachable from the housing 9 in the X direction. For example, a pump opening (reference sign not shown) for making the pump 4 attachable and detachable is provided at the front panel 92. The pump 4 is attached to and detached from the housing 9 via the pump opening. In a state where the pump 4 is attached to the housing 9, a part of the pump 4 such as a handle 41 is exposed from the pump opening. The handle 41 is gripped by an attaching and detaching worker of the pump 4.

As shown in FIG. 10, the tank 5 is a substantially cuboid having six outer faces. The tank 5 has a pair of outer faces parallel to an XY plane, a pair of outer faces parallel to a YZ plane, and a pair of outer faces parallel to a ZX plane. In the tank 5, the X direction is a long direction. The tank 5 is flat in the Z direction relative to the heat exchanger 3. The tank 5 internally has a space for storing the refrigerant.

The tank 5 has a tank-side supply port (not illustrated) on the outer face on the other side in the Z direction. The secondary flow path 2 has a flow path-side supply port 20 (see FIG. 6) connected to the tank-side supply port. The flow path-side supply port 20 is arranged in the flow path pipe 22. This allows the refrigerant to be supplied from the tank 5 to the secondary flow path 2 via the flow path-side supply port 20. When the flow rate of the secondary refrigerant circulating in the cooling system 1000 decreases, the refrigerant is supplied from the tank 5 to the secondary flow path 2. Due to this, the flow rate of the secondary refrigerant circulating in the cooling system 1000 can be maintained constant.

For example, the tank 5 has a filling port 51, a liquid level check window 52, and an air vent valve 53. The filling port 51 is used to replenish the tank 5 with the refrigerant. The liquid level check window 52 is made of a translucent material and is used to check the internal state of the tank 5. The air vent valve 53 is used to release the internal air of tank 5 to the outside.

The control circuit 6 (see FIGS. 5 to 7) is mounted on a control board 60. The circuit mounted on the control board 60 is the control circuit 6. The control board 60 is mounted with a microcomputer, a memory, and the like.

Although not illustrated, the control circuit 6 is connected to a temperature and humidity sensor that detects the temperature and humidity of the inside of the CDU 100, and is connected to a temperature sensor that detects the temperature of the primary refrigerant and a temperature sensor that detects the temperature of the secondary refrigerant. The control circuit 6 controls the pump 4 and controls the opening degree of each of the control valves V1 and V2.

The power supply unit 7 (see FIGS. 4 to 7) includes a power supply circuit. The power supply unit 7 is connected to a commercial power supply, and generates a direct-current voltage from an alternating-current voltage. The power supply unit 7 supplies electric power to a power-supplied unit that operates by receiving power supply, such as the pump 4, the control circuit 6, the control valves V1 and V2, and various sensors.

For example, the power supply unit 7 has a power supply terminal on one side in the X direction. For this, the back panel 91 is provided with a power supply unit opening. The power supply terminal of the power supply unit 7 is exposed to the outside from the accommodation region 90 through the power supply unit opening. The number of power supply units 7 installed is 2. The two power supply units 7 are stacked in the Z direction.

The touchscreen 8 (see FIGS. 2 and 4) is connected to the control circuit 6. The control circuit 6 causes the touchscreen 8 to display various types of information. For example, the touchscreen 8 displays an operating status of the cooling system 1000. The touchscreen 8 also displays measurement values of the temperature and humidity sensor and the temperature sensors. The touchscreen 8 is one of the power-supplied units that operate by receiving power supply from the power supply unit 7.

The front panel 92 has a touchscreen opening (reference sign not shown). The display surface of the touchscreen 8 is exposed to the outside from the accommodation region 90 through the touchscreen opening.

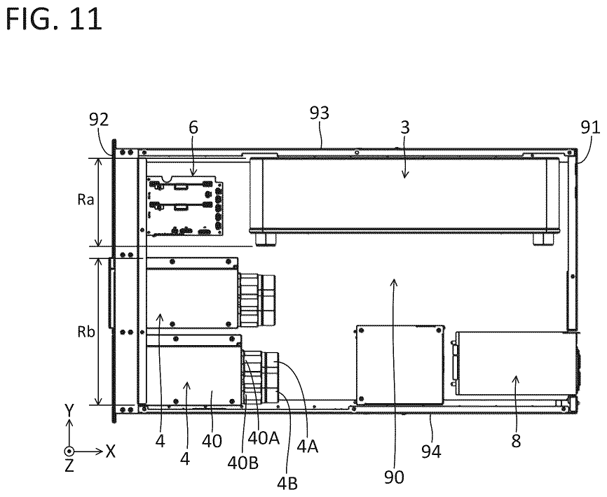

FIG. 11 is a view showing a positional relationship between the heat exchanger 3 and the pump 4 of the CDU 100 according to the example embodiment. FIG. 11 corresponds to a plan view of the accommodation region 90 as viewed from one side (upper side) in the Z direction.

In the present example embodiment, the entirety of the heat exchanger 3 is positioned on the Y direction side relative to the pump 4. That is, the entirety of the heat exchanger 3 does not face the pump 4 in the X direction.

Specifically, in plan view from the Z direction, the heat exchanger 3 is arranged along the panel 93 on one side in the Y direction. On the other hand, the pump 4 is arranged along the panel 94 on the other side in the Y direction. That is, the entirety of the heat exchanger 3 is positioned on one side in the Y direction relative to the pump 4. In FIG. 11, the range in the Y direction of the region where the heat exchanger 3 is arranged is indicated by Ra, and the range in the Y direction of the region where the pump 4 is arranged is indicated by Rb. Since the entirety of the heat exchanger 3 is positioned on one side in the Y direction relative to the pump 4, the range Ra does not overlap the range Rb.

In the present example embodiment, since the entirety of the heat exchanger 3 is positioned on one side in the Y direction relative to the pump 4, the heat exchanger 3 does not face the pump 4 in the X direction. Specifically, the heat exchanger 3 is arranged adjacent to the panel 91 on one side in the X direction and is arranged adjacent to the panel 93 on one side in the Y direction. Therefore, it is not necessary to ensure an arrangement space of the pump 4 in the region on the other side in the X direction of the heat exchanger 3 in the accommodation region 90, and it is accordingly possible to increase the size in the long direction of the heat exchanger 3. That is, the surface area of each heat transfer plate of the heat exchanger 3 can be increased. The larger the size of the heat exchanger 3 is, the larger the number of thermal contact points between the primary refrigerant and the secondary refrigerant in the heat exchanger 3 is, and therefore the cooling performance (performance of cooling the secondary refrigerant) of the heat exchanger 3 is improved. As a result, the cooling performance of the CDU 100 is improved.

The plurality of pumps 4 are arranged in the accommodation region 90. The plurality of pumps 4 are arrayed in the Y direction.

Therefore, in the present example embodiment, the entirety of the heat exchanger 3 is positioned on one side in the Y direction relative to the pump 4 on one side in the Y direction among the plurality of pumps 4. That is, the entirety of the heat exchanger 3 is positioned on the Y direction side relative to any of the pumps 4. With this configuration, the size of the heat exchanger 3 can be increased even when the plurality of pumps 4 exist. By bringing the plurality of pumps 4 closer to the other side in the Y direction than the heat exchanger 3, piping of the primary flow path 1 and the secondary flow path 2 is facilitated.

Each of the pump inlet 40A and the pump outlet 40B is a tubular member protruding from the pump body 40 to one side in the X direction. The pump inlet-side flow path 4A is connected in the X direction with respect to the pump inlet 40A, and the pump outlet-side flow path 4B is connected in the X direction with respect to the pump outlet 40B.

In the present example embodiment, the pump inlet-side flow path 4A and the pump outlet-side flow path 4B extend in the X direction on the Y direction side relative to the heat exchanger 3. The pump inlet-side flow path 4A extends from the pump body 40 to one side in the X direction, and the pump outlet-side flow path 4B extends from the pump body 40 to one side in the X direction. This allows the secondary flow path 2 to be easily routed when the secondary flow path 2 is routed in a region on one side in the X direction of the pump 4 in the accommodation region 90. It is necessary to move the pump 4 in the X direction when the pump 4 is attached to and detached from the housing 9, but the attachment and detachment of the pump 4 are facilitated.

In the present example embodiment, as shown in FIG. 7, the part of the secondary flow path 2 connecting the housing secondary outlet 92B and the pump outlet 40B extends in the X direction on the Y direction side (specifically, one side in the Y direction) relative to the heat exchanger 3. The part of the secondary flow path 2 connecting the housing secondary outlet 92B and the pump outlet 40B is the flow path pipe 24 and the flow path pipe 25. This configuration can easily obtain the secondary flow path 2 (outlet side) from the pump 4 to the housing secondary outlet 92B.

In the present example embodiment, as shown in FIGS. 5 to 8, the flow path connection face 300 is directed to the other side in the Y direction. Here, the flow path connection face 300 is a face having the HEX primary inlet 31A, the HEX primary outlet 31B, the HEX secondary inlet 32A, and the HEX secondary outlet 32B. That is, the HEX primary inlet 31A, the HEX primary outlet 31B, the HEX secondary inlet 32A, and the HEX secondary outlet 32B are directed to the other side in the Y direction.

With this configuration, the primary flow path 1 can be easily connected to the heat exchanger 3 (specifically, the HEX primary inlet 31A and the HEX primary outlet 31B). The secondary flow path 2 can be easily connected to the heat exchanger 3 (specifically, the HEX secondary inlet 32A and the HEX secondary outlet 32B). Since the heat exchanger 3 is arranged adjacent to the panels 91 and 93, the HEX primary inlet 31A, the HEX primary outlet 31B, the HEX secondary inlet 32A, and the HEX secondary outlet 32B are concentrated on the flow path connection face 300, whereby the heat exchanger 3 can be easily increased in size.

In the present example embodiment, the heat exchanger 3 and the pump 4 do not face each other in the X direction. That is, a region where the pump 4 does not exist is generated on the X direction side of the heat exchanger 3 in the accommodation region 90. In this region, neither the primary flow path 1 nor the secondary flow path 2 is arranged.

Therefore, in the present example embodiment, as shown in FIGS. 5 to 7, the control circuit 6 is arranged in a region on the X direction side of the heat exchanger 3 in the accommodation region 90. Specifically, the heat exchanger 3 is arranged closer to one side in the X direction along the back panel 91. Due to this, a space in which the control circuit 6 can be arranged is generated in a region on the other side in the X direction of the heat exchanger 3 in the accommodation region 90, and therefore the control circuit 6 is arranged in the space.

Here, the arrangement space of the control circuit 6 is smaller than the arrangement space of the pump 4. Due to this, even if the control circuit 6 is arranged in a region on the other side in the X direction of the heat exchanger 3 in the accommodation region 90, an increase in size of the heat exchanger 3 in the X direction is not hindered. That is, it is possible to increase the size of the heat exchanger 3 while ensuring the arrangement space for the control circuit 6.

In the present example embodiment, the control circuit 6 is arranged in a region on the Y direction side of the pump 4 in the accommodation region 90. That is, the control circuit 6 is arranged in a region on the other side in the X direction of the heat exchanger 3 and on one side in the Y direction of the pump 4 in the accommodation region 90.

In this configuration, the control circuit 6 has a smaller dimension in the X direction than that of the pump 4. Due to this, the control circuit 6 can be easily arranged in the region on the other side in the X direction of the heat exchanger 3 and on one side in the Y direction of the pump 4 in the accommodation region 90.

For example, the control board 60 is arranged such that the mounting face of the control board 60 is perpendicular to the Z direction. However, the present disclosure is not limited to this. The control board 60 may be arranged such that the mounting face of the control board 60 is perpendicular to the X direction or the Y direction.

The arrangement space of the control circuit 6 is a space on the other side in the X direction of the heat exchanger 3 and the tank 5 and on one side in the Y direction of the pump 4, and the primary flow path 1 and the secondary flow path 2 do not exist there. Furthermore, the arrangement space of the control circuit 6 is defined by a face having no pipe connection of the heat exchanger 3 and a face having no pipe connection of the tank 5, as well as a face having no pipe connection of the face of the pump 4. This can suppress an adverse effect on the control circuit 6 due to liquid leakage.

The touchscreen 8 is arranged in a space on the other side in the X direction of the heat exchanger 3. Specifically, the touchscreen 8 is adjacent on the other side in the X direction to the control circuit 6. This facilitates connection between the touchscreen 8 and the control circuit 6 without affecting insertion and removal of the pump 4.

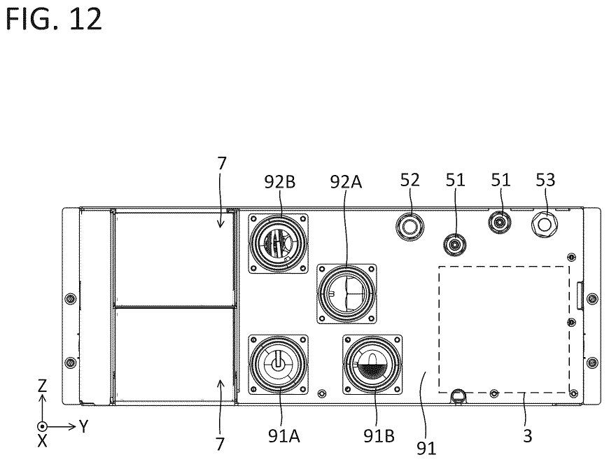

FIG. 12 is a plan view of the CDU 100 according to the example embodiment as viewed from one side in the X direction. In FIG. 12, the arrangement position of the heat exchanger 3 is indicated by a broken line.

In the present example embodiment, as shown in FIGS. 5 to 7, the power supply unit 7 is positioned on the Y direction side relative to the heat exchanger 3 and on the X direction side relative to the pump 4. This allows the power supply unit 7 to be easily arranged in the accommodation region 90 without interfering with the heat exchanger 3 and the pump 4.

In the present example embodiment, the heat exchanger 3 is arranged on one side in the Y direction, and the power supply unit 7 is arranged at an interval on the other side in the Y direction relative to the heat exchanger 3. As shown in FIG. 12, the housing primary inlet 91A, the housing primary outlet 91B, the housing secondary inlet 92A, and the housing secondary outlet 92B are arranged in the Y direction between the heat exchanger 3 and the power supply unit 7 in plan view from the X direction. This allows at least a part of the primary flow path 1 to be routed in the Y direction between the heat exchanger 3 and the power supply unit 7, and allows at least a part of the secondary flow path 2 to be routed in the Y direction between the heat exchanger 3 and the power supply unit.

In the present example embodiment, as shown in FIGS. 4 and 10, the tank 5 is arranged so as to at least partially overlap, in the Z direction, the heat exchanger 3 on one side in the Z direction (i.e., the upper side) relative to the heat exchanger 3. In plan view from the Z direction, a part of the tank 5 protrudes from the heat exchanger 3, and the part of the tank 5 protruding from the heat exchanger 3 is connected in the Z direction to the flow path pipe 22. That is, the tank 5 is connected in the Z direction to the secondary flow path 2.

With this configuration, air bubbles in the secondary flow path 2 are easily collected in the tank 5. This can reduce air bubbles in the secondary flow path 2. Since the heat exchanger 3 and the tank 5 do not overlap each other in the horizontal direction, the heat exchanger 3 can be easily increased in size.

The tank 5 is positioned on one side in the Z direction (i.e., the upper side) relative to the secondary flow path 2. A connection port between the tank 5 and the secondary flow path 2 is provided on a face of the tank 5 on the other side in the Z direction (i.e., the lower side). Therefore, even in a state where the refrigerant inside the tank 5 decreases, the refrigerant can be supplied from the tank 5 to the secondary flow path 2.

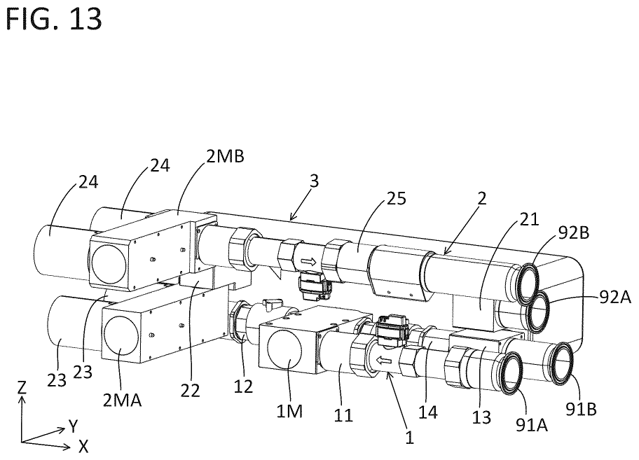

FIG. 13 is a perspective view of the primary flow path 1 and the secondary flow path 2 of the CDU 100 according to the example embodiment as viewed from the side opposite to the heat exchanger 3 side.

The secondary refrigerant flowing into the heat exchanger 3 via the secondary flow path 2 is higher in temperature than the primary refrigerant flowing into the heat exchanger 3 via the primary flow path 1. At least a part of the secondary flow path 2 overlaps the primary flow path 1 in the Z direction. In other words, at least a part of the secondary flow path 2 is arranged in the vicinity of the primary flow path 1. Therefore, due to the temperature difference between the primary flow path 1 and the secondary flow path 2, dew condensation occurs on an outer peripheral face of the primary flow path 1, and water droplets can fall from the outer peripheral face of the primary flow path 1.

Therefore, in the present example embodiment, the secondary flow path 2 is positioned on one side in the Z direction relative to the primary flow path 1. In other words, the secondary flow path 2 is positioned above the primary flow path 1. In this configuration, even if a water droplet falls from the outer peripheral face of the primary flow path 1, the water droplet does not adhere to the outer peripheral face of the secondary flow path 2. This can suppress malfunction of a sensor due to adhesion of water droplets to the sensor arranged in the secondary flow path 2, for example.

Each of the primary flow path 1 and the secondary flow path 2 can be provided with a leak sensor. This enables detection of liquid leakage in each of the primary flow path 1 and the secondary flow path 2.

The example embodiment of the present disclosure has been described above. The scope of the present disclosure is not limited to the above-described example embodiment. The present disclosure can be implemented with various modifications within a scope not departing from the gist of the disclosure. The above-described example embodiment can be appropriately and optionally combined.

The present disclosure can have the following configurations (1) to (11).
(1) A refrigerant circulation device including: a primary flow path serving as a flow path of a primary refrigerant; a secondary flow path serving as a flow path of a secondary refrigerant; a heat exchanger connected to the primary flow path and the secondary flow path; a pump connected to the secondary flow path; and a housing including an accommodation region, in which the accommodation region extends in a first direction and a second direction intersecting each other, and has a dimension longer in the first direction than in the second direction, the housing accommodates the primary flow path, the secondary flow path, the heat exchanger, and the pump in the accommodation region, and an entirety of the heat exchanger is positioned on one side in the second direction relative to the pump.
(2) The refrigerant circulation device according to (1) including a plurality of the pumps, in which an entirety of the heat exchanger is positioned on one side in the second direction relative to any of the pumps.
(3) The refrigerant circulation device according to (1) or (2), in which the pump includes: a pump inlet serving as an inflow port of the secondary refrigerant, a pump outlet serving as an outflow port of the secondary refrigerant, a pump inlet-side flow path connecting the pump inlet and the secondary flow path, and a pump outlet-side flow path connecting the pump outlet and the secondary flow path, and the pump inlet-side flow path and the pump outlet-side flow path extend in the first direction on the second direction side relative to the heat exchanger.
(4) The refrigerant circulation device according to (3), in which the housing includes a housing secondary outlet serving as an outflow port of the secondary refrigerant; and a portion of the secondary flow path, the portion connecting the housing secondary outlet and the pump outlet extends in the first direction on the second direction side relative to the heat exchanger.
(5) The refrigerant circulation device according to any of (1) to (4), in which an entirety of the heat exchanger is positioned on one side in the second direction relative to the pump, the heat exchanger includes: a HEX primary inlet connected to the primary flow path and serving as an inflow port of the primary refrigerant, a HEX primary outlet connected to the primary flow path and serving as an outflow port of the primary refrigerant, a HEX secondary inlet connected to the secondary flow path and serving as an inflow port of the secondary refrigerant, a HEX secondary outlet connected to the secondary flow path and serving as an outflow port of the secondary refrigerant, and a HEX housing having a flow path connection surface on which the HEX primary inlet, the HEX primary outlet, the HEX secondary inlet, and the HEX secondary outlet are arranged, and the flow path connection surface opposes another side in the second direction.
(6) The refrigerant circulation device according to any of (1) to (5) including a control circuit, in which the housing accommodates the control circuit in the accommodation region, and the control circuit is in a portion of the accommodation region, the region on the first direction side of the heat exchanger.
(7) The refrigerant circulation device according to (6), in which the control circuit is in a portion of the accommodation region, the region on the second direction side of the pump, and the control circuit is smaller in dimension in the first direction than the pump.
(8) The refrigerant circulation device according to any of (1) to (7) including a power supply assembly, in which the housing accommodates the power supply assembly in the accommodation region, and the power supply assembly is positioned on the second direction side relative to the heat exchanger and on the first direction side relative to the pump.
(9) The refrigerant circulation device according to (8), in which the heat exchanger is on one side in the second direction, the power supply assembly is arranged at an interval on another side in the second direction with respect to the heat exchanger, the housing includes: a housing primary inlet connected to the primary flow path and serving as an inflow port of the primary refrigerant, a housing primary outlet connected to the primary flow path and serving as an outflow port of the primary refrigerant, a housing secondary inlet connected to the secondary flow path and serving as an inflow port of the secondary refrigerant, a housing secondary outlet connected to the secondary flow path and serving as an outflow port of the secondary refrigerant, and the housing primary inlet, the housing primary outlet, the housing secondary inlet, and the housing secondary outlet are arranged in the second direction between the heat exchanger and the power supply assembly.
(10) The refrigerant circulation device according to any of (1) to (9) including a tank that stores a refrigerant used as the secondary refrigerant, in which the housing accommodates the tank in the accommodation region, the tank is arranged such that at least a portion of the tank overlaps in a third direction with respect to the heat exchanger on one side of the third direction intersecting the first direction and the second direction relative to the heat exchanger, and the tank is connected in the third direction with respect to the secondary flow path.
(11) The refrigerant circulation device according to any of (1) to (10), in which the secondary refrigerant flowing into the heat exchanger through the secondary flow path is higher in temperature than the primary refrigerant flowing into the heat exchanger through the primary flow path, and the secondary flow path is positioned on one side in a third direction intersecting the first direction and the second direction relative to the primary flow path.

Example embodiments of the present disclosure can be used in, for example, refrigerant circulation devices included in cooling systems that cool electronic devices and electronic components.

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A refrigerant circulation device, comprising:
a primary flow path serving as a flow path of a primary refrigerant;
a secondary flow path serving as a flow path of a secondary refrigerant;
a heat exchanger connected to the primary flow path and the secondary flow path;
a pump connected to the secondary flow path; and
a housing including an accommodation region; wherein
the accommodation region extends in a first direction and a second direction intersecting each other, and has a dimension longer in the first direction than in the second direction;
the housing accommodates the primary flow path, the secondary flow path, the heat exchanger, and the pump in the accommodation region; and
an entirety of the heat exchanger is positioned on one side in the second direction relative to the pump.

2. The refrigerant circulation device according to claim 1, further comprising:
a plurality of the pumps; wherein
an entirety of the heat exchanger is positioned on one side in the second direction relative to any of the pumps.

3. The refrigerant circulation device according to claim 1, wherein
the pump includes:
a pump inlet serving as an inflow port of the secondary refrigerant;
a pump outlet serving as an outflow port of the secondary refrigerant;
a pump inlet-side flow path connecting the pump inlet and the secondary flow path; and
a pump outlet-side flow path connecting the pump outlet and the secondary flow path; and
the pump inlet-side flow path and the pump outlet-side flow path extend in the first direction on the second direction side relative to the heat exchanger.

4. The refrigerant circulation device according to claim 3,
wherein the housing includes a housing secondary outlet serving as an outflow port of the secondary refrigerant; and
a portion of the secondary flow path, the portion connecting the housing secondary outlet and the pump outlet extends in the first direction on the second direction side relative to the heat exchanger.

5. The refrigerant circulation device according to claim 1, wherein
an entirety of the heat exchanger is positioned on one side in the second direction relative to the pump;
the heat exchanger includes:
a HEX primary inlet connected to the primary flow path and serving as an inflow port of the primary refrigerant;
a HEX primary outlet connected to the primary flow path and serving as an outflow port of the primary refrigerant;
a HEX secondary inlet connected to the secondary flow path and serving as an inflow port of the secondary refrigerant;
a HEX secondary outlet connected to the secondary flow path and serving as an outflow port of the secondary refrigerant; and
a HEX housing including a flow path connection surface on which the HEX primary inlet, the HEX primary outlet, the HEX secondary inlet, and the HEX secondary outlet are arranged; and
the flow path connection surface opposes another side in the second direction.

6. The refrigerant circulation device according to claim 1, further comprising:
a control circuit; wherein
the housing accommodates the control circuit in the accommodation region; and
the control circuit is in a portion of the accommodation region on a first direction side of the heat exchanger.

7. The refrigerant circulation device according to claim 6, wherein
the control circuit is in a portion of the accommodation region on a second direction side of the pump; and
the control circuit is smaller in dimension in the first direction than the pump.

8. The refrigerant circulation device according to claim 1, further comprising:
a power supply assembly; wherein
the housing accommodates the power supply assembly in the accommodation region; and
the power supply assembly is positioned on the second direction side relative to the heat exchanger and on the first direction side relative to the pump.

9. The refrigerant circulation device according to claim 8, wherein
the heat exchanger is on one side in the second direction;
the power supply assembly is arranged at an interval on another side in the second direction with respect to the heat exchanger;
the housing includes:
a housing primary inlet connected to the primary flow path and serving as an inflow port of the primary refrigerant;
a housing primary outlet connected to the primary flow path and serving as an outflow port of the primary refrigerant;
a housing secondary inlet connected to the secondary flow path and serving as an inflow port of the secondary refrigerant; and
a housing secondary outlet connected to the secondary flow path and serving as an outflow port of the secondary refrigerant; and
the housing primary inlet, the housing primary outlet, the housing secondary inlet, and the housing secondary outlet are arranged in the second direction between the heat exchanger and the power supply assembly.

10. The refrigerant circulation device according to claim 1, further comprising:
a tank that stores a refrigerant used as the secondary refrigerant; wherein
the housing accommodates the tank in the accommodation region;
the tank is arranged such that at least a portion of the tank overlaps in a third direction with respect to the heat exchanger on one side of the third direction intersecting the first direction and the second direction relative to the heat exchanger; and
the tank is connected in the third direction with respect to the secondary flow path.

11. The refrigerant circulation device according to claim 1, wherein
the secondary refrigerant flowing into the heat exchanger through the secondary flow path is higher in temperature than the primary refrigerant flowing into the heat exchanger through the primary flow path; and
the secondary flow path is positioned on one side in a third direction intersecting the first direction and the second direction relative to the primary flow path.
